(19) United States
(12) Patent Application Publication
(10) Pub. No.: US 2025/0336734 A1
(43) Pub. Date: Oct. 30, 2025

(54) SEMICONDUCTOR DEVICE, MODULE, AND PHASED ARRAY ANTENNA DEVICE

(71) Applicant: SUMITOMO ELECTRIC DEVICE INNOVATIONS, INC., Kanagawa (JP)

(72) Inventors: Masakazu TAKAHASHI, Kanagawa (JP); Kunihiro USAMI, Kanagawa (JP)

(21) Appl. No.: 19/188,492

(22) Filed: Apr. 24, 2025

(30) Foreign Application Priority Data
Apr. 30, 2024 (JP) 2024-073766

(51) Int. Cl. H01L 23/057; H01L 23/538; H01L 25/07; H01Q 3/36; H03F 3/19

(52) U.S. Cl. CPC H01L 23/057; H01L 23/538; H01L 25/072; H01Q 3/36; H03F 3/19; H03F 2200/451

(57) ABSTRACT

A semiconductor device includes a semiconductor chip, and a package including an accommodating portion that houses the semiconductor chip, and a first flange and a second flange arranged along a first direction with the accommodating portion interposed therebetween. A lower surface of a first end portion of the first flange is positioned above a mounting surface of the accommodating portion, and a first distance between the lower surface of the first end portion and the mounting surface in a second direction is equal to or greater than a second distance between an upper surface of a second end portion of the second flange and the mounting surface in the second direction. The first end portion has a 10 first opening or a first notch penetrating the first end portion, and the second end portion has a second opening or a second notch penetrating the second end portion.

### CROSS REFERENCE TO RELATED APPLICATIONS

This application is based on claims priority to Japanese Patent Application No. 2024-073766 filed on Apr. 30, 2024, and the entire contents of the Japanese patent application are incorporated herein by reference.

### TECHNICAL FIELD

The present disclosure relates to semiconductor devices, modules, and phased array antenna devices.

### BACKGROUND

As known in the art, a semiconductor device may use a package having a pair of flanges that are positioned opposite each other across a main body in a first direction. The main body is mounted on a substrate by the pair of flanges. The flanges are positioned at different locations along a second direction orthogonal to the first direction (for example, see patent literature 1: Japanese Unexamined Utility Model (Registration) Application Publication No. 5-46043).

### SUMMARY OF INVENTION

A semiconductor device according to an embodiment of the present disclosure includes a semiconductor chip, and a package including an accommodating portion that houses the semiconductor chip, and a first flange and a second flange arranged along a first direction with the accommodating portion being interposed between the first flange and the second flange, the first flange being positioned in the first direction relative to the accommodating portion, the second flange being positioned in an opposite direction to the first direction relative to the accommodating portion. A lower surface of a first end portion, in the first direction, of the first flange is positioned above a mounting surface of the accommodating portion, and a first distance between the lower surface of the first end portion and the mounting surface in a second direction orthogonal to the mounting surface is equal to or greater than a second distance between an upper surface of a second end portion, in the opposite direction, of the second flange and the mounting surface in the second direction. The first end portion has at least one first opening or at least one first notch penetrating the first end portion in the second direction, and the second end portion has at least one second opening or at least one second notch penetrating the second end portion in the second direction.

### BRIEF DESCRIPTION OF THE DRAWINGS

FIG. 1 is a plan view of a semiconductor device according to a first embodiment.

FIG. 2 is a side view of the semiconductor device according to the first embodiment.

FIG. 3 is a cross-sectional view taken along line A-A of FIG. 1.

FIG. 4 is a plan view of a module according to the first embodiment.

FIG. 5 is a cross-sectional view taken along line A-A of FIG. 4.

FIG. 6 is a plan view of a module according to a first comparative example.

FIG. 7 is a plan view of a module according to a second comparative example.

FIG. 8 is a side view of a semiconductor device according to a modification 1 of the first embodiment.

FIG. 9 is a side view of a module according to the modification 1 of the first embodiment.

FIG. 10 is a plan view of a semiconductor device according to a modification 2 of the first embodiment.

FIG. 11 is a front view of antennas in a phased array antenna device according to a second embodiment.

FIG. 12 is a block diagram of the phased array antenna device according to the second embodiment.

FIG. 13 is an oblique view of a portion of the phased array antenna device according to the second embodiment.

FIG. 14 is a plan view of a portion of the phased array antenna device according to the second embodiment.

FIG. 15 is a side view of a portion of the phased array antenna device according to the second embodiment.

FIG. 16 is a front view of a module and antennas of a portion of the phased array antenna device according to the second embodiment.

### DETAILED DESCRIPTION

As disclosed in patent literature 1, a mounting interval of a plurality of semiconductor devices in the first direction can be shortened by making the positions of the flanges in the second direction different from each other. However, when the semiconductor devices are mounted on the substrate, stress-related characteristics and the like are deteriorated, and the semiconductor devices are unstable.

An object of the present disclosure is to provide a semiconductor device that can be stably mounted at a short mounting interval, a module, and a phased array antenna.

### [Description of Embodiments of Present Disclosure]

First, embodiments of the present disclosure will be listed and described.

(1) A semiconductor device according to an embodiment of the present disclosure includes a semiconductor chip, and a package including an accommodating portion that houses the semiconductor chip, and a first flange and a second flange arranged along a first direction with the accommodating portion being interposed between the first flange and the second flange, the first flange being positioned in the first direction relative to the accommodating portion, the second flange being positioned in an opposite direction to the first direction relative to the accommodating portion. A lower surface of a first end portion, in the first direction, of the first flange is positioned above a mounting surface of the accommodating portion, and a first distance between the lower surface of the first end portion and the mounting surface in a second direction orthogonal to the mounting surface is equal to or greater than a second distance between an upper surface of a second end portion, in the opposite direction, of the second flange and the mounting surface in the second direction. The first end portion has at least one first opening or at least one first notch penetrating the first end portion in the second direction, and the second end portion has at least one second opening or at least one second notch penetrating the second end portion in the second direction. Thus, a mounting interval of semiconductor devices with this configuration can be shortened and the semiconductor devices can be stably mounted.

(2) In (1), the at least one first opening or the at least one first notch may comprise a plurality of first openings or a plurality of first notches that are arranged in a third direction orthogonal to the first direction and the second direction, and the at least one second opening or the at least one second notch may comprise a plurality of second openings or a plurality of second notches that are arranged in the third direction. Thus, the semiconductor device can be stably mounted.
(3) In (2), at least two of the plurality of first openings or at least two of the plurality of first notches may be arranged with a center line of the package in the third direction being interposed therebetween, and at least two of the plurality of second openings or at least two of the plurality of second notches may be arranged with the center line of the package in the third direction being interposed therebetween. Thus, the semiconductor device can be stably mounted.
(4) In any one of (1) to (3), a position of the at least one first opening or the at least one first notch in the third direction orthogonal to the first direction and the second direction may coincide with a position of the at least one second opening or the at least one second notch in the third direction. Thus, semiconductor devices can be arranged in the first direction.
(5) In any one of (1) to (4), an upper surface of the first end portion may be positioned above the upper surface of the second end portion with respect to the mounting surface. Thus, the first end portion can be easily formed.
(6) In any one of (1) to (4), the first flange and the second flange may each include a first layer and a second layer stacked in the second direction, the first end portion may include the second layer and does not have to include the first layer, and the second end portion may include the first layer and does not have to include the second layer. Thus, the semiconductor device can be stably mounted.
(7) In any one of (1) to (6), the at least one first opening or the at least one first notch, and the at least one second opening or at least one the second notch, may each be configured to allow a fixture fixing the semiconductor device to a substrate to pass through. Thus, the semiconductor device can be stably mounted.
(8) A module according to an embodiment of the present disclosure may include a substrate; a first semiconductor device that has the same configuration as the semiconductor device of any one of (1) to (7), the first semiconductor device being mounted on the substrate such that the mounting surface is positioned on an upper surface of the substrate; and a second semiconductor device that has the same configuration as the semiconductor device of any one of (1) to (7), the second semiconductor device being mounted on the substrate such that the mounting surface is positioned on the upper surface of the substrate. The second end portion of the second semiconductor device is provided between the first end portion of the first semiconductor device and the substrate, and the first semiconductor device and the second semiconductor device are fixed on the substrate by a common fixture passing through the at least one first opening or the at least one first notch, and through the at least one second opening or the at least one second notch. Thus, the mounting interval of the semiconductor devices can be shortened and the semiconductor devices can be stably mounted.
(9) In (8), an arrangement direction of the first semiconductor device and the second semiconductor device may coincide with the first direction of the first semiconductor device and the first direction of the second semiconductor device. Thus, the semiconductor devices can be arranged in the first direction.
(10) A phased array antenna device according to an embodiment of the present disclosure may include the module according to (9), and a first antenna and a second antenna arranged in the arrangement direction. A third direction orthogonal to the first direction and the second direction of the first semiconductor device coincides with the a direction orthogonal to the first direction and the second direction of in the second semiconductor device, the first antenna overlaps the first semiconductor device when viewed from the third direction, and the second antenna overlaps the second semiconductor device when viewed from the third direction. Thus, the phased array antenna device that handles higher frequencies can be provided.
(11) In (10), the first semiconductor device may include a first amplification circuit, the second semiconductor device may include a second amplification circuit, the first amplification circuit may output an amplified high frequency signal to the first antenna, and the second amplification circuit may output an amplified high frequency signal to the second antenna. Thus, the rise in temperature of the semiconductor device is reduced.

### [Details of Embodiments of Present Disclosure]

Specific examples of a semiconductor device, a module, and a phased array antenna device according to embodiments of the present disclosure will be described below with reference to the drawings. The present disclosure is not limited to these examples, but is defined by the scope of the claims, and is intended to include all modifications within the meaning and scope equivalent to the scope of the claims.

### (Semiconductor Device of First Embodiment)

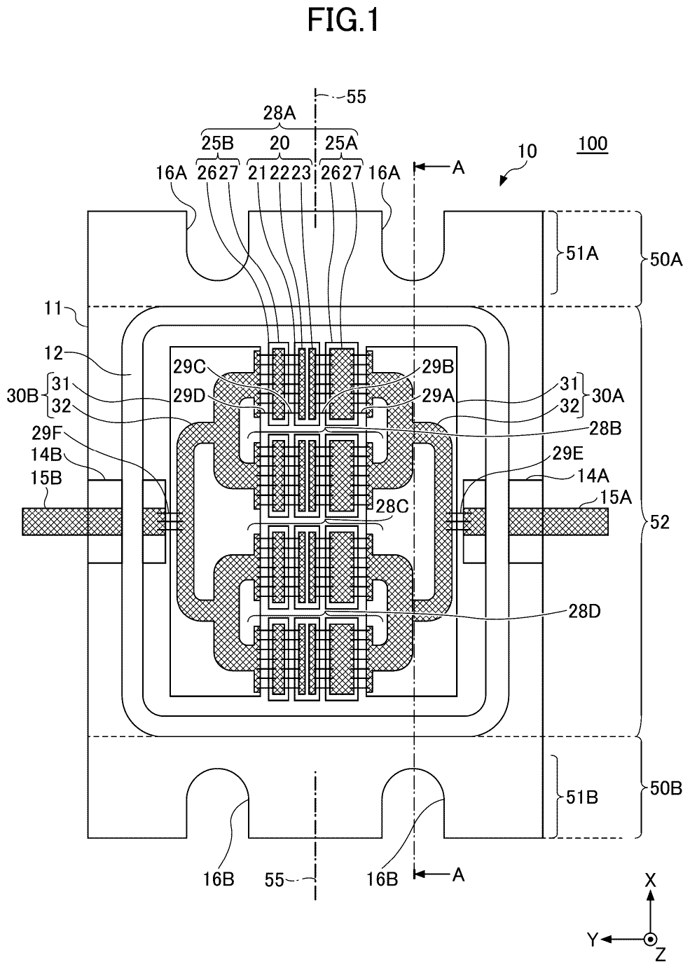

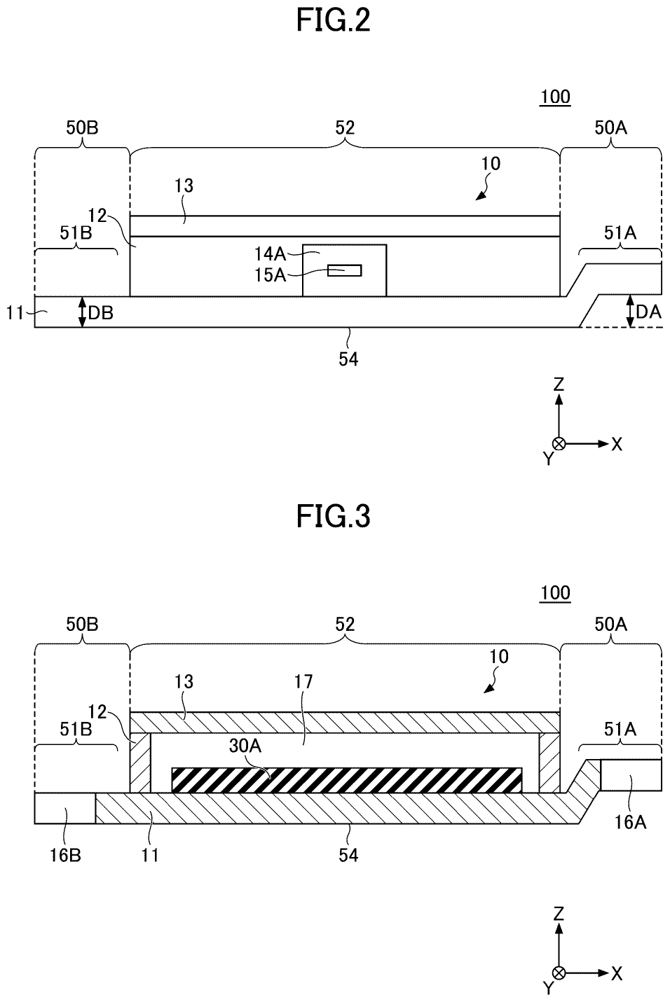

FIG. 1 is a plan view of a semiconductor device according to a first embodiment. In FIG. 1, a lid body is shown in a transparent manner. FIG. 2 is a side view of the semiconductor device according to the first embodiment. FIG. 3 is a cross-sectional view taken along line A-A of FIG. 1. A direction orthogonal to a mounting surface 54 of a base portion 11 is defined as a Z direction (second direction), a direction in which flanges 50B and 50A are arranged with an accommodating portion 52 being interposed between flanges 50A and 50B is defined as an X direction (first direction), and a direction orthogonal to the X direction and the Z direction is defined as a Y direction (third direction).

As shown in FIGS. 1 to 3, a semiconductor device 100 includes a package 10, amplifiers 28A to 28D, and line chips 30A and 30B. Package 10 includes base portion 11, a frame body 12, a lid body 13, feedthroughs 14A and 14B, and leads 15A and 15B.

Base portion 11 has a substantially rectangular plate shape in a plan view. Base portion 11 includes flanges 50A and 50B, and flanges 50A and 50B are disposed so that accommodating portion 52 is interposed therebetween in the X direction. Accommodating portion 52 includes a portion of base portion 11, the portion being interposed between flanges 50A and 50B, and further includes frame body 12 and lid body 13. Amplifiers 28A to 28D and line chips 30A and 30B are accommodated in accommodating portion 52.

Base portion 11 has mounting surface 54. Mounting surface 54 is a flat surface and is a surface to be mounted on a substrate 35 described later. Flange 50A has an end portion 51A, and flange 50B has an end portion 51B. End portion 51A is a portion including an end of flange 50A in the positive X direction, and end portion 51B is a portion including an end of flange 50B in the negative X direction. The lower surface of end portion 51A is positioned above (in the positive Z direction of) mounting surface 54 of base portion 11. The distance between mounting surface 54 and the lower surface of end portion 51A in the Z direction is DA. The lower surface of end portion 51B is at the same position as mounting surface 54 in the Z direction. The distance between mounting surface 54 and the upper surface of end portion 51B in the Z direction is DB.

End portions 51A and 51B have notches 16A and 16B, respectively. Notch 16A penetrates end portion 51A in the Z direction and is open to the side of flange 50A in the positive X direction. Notch 16B penetrates end portion 51B in the Z direction and is open to the side of flange 50B in the negative X direction. Two notches 16A are arranged along the Y direction, and two notches 16B are arranged along the Y direction.

Frame body 12 is provided on base portion 11. Frame body 12 has a substantially rectangular shape in a plan view. Lid body 13 is provided on frame body 12. Base portion 11, frame body 12, and lid body 13 form a void 17. Feedthrough 14A penetrates, in the Y direction, the side of frame body 12 in the negative Y direction, and feedthrough 14B penetrates, in the Y direction, the side of frame body 12 in the positive Y direction. Lead 15A penetrates feedthrough 14A in the Y direction, and lead 15B penetrates feedthrough 14B in the Y direction. Base portion 11, frame body 12, and leads 15A and 15B are metal layers such as copper layers or the like. Feedthroughs 14A and 14B are insulating layers such as layers of ceramic, resin, or the like. Lid body 13 is a metal layer such as a copper layer or the like or an insulating layer such as a ceramic layer or the like.

Amplifiers 28A to 28D and line chips 30A and 30B are provided on base portion 11 in frame body 12. Amplifiers 28A to 28D are arranged along the X direction. Line chips 30A and 30B are positioned opposite each other across amplifiers 28A to 28D in the Y direction.

Amplifiers 28A to 28D each include a semiconductor chip 20, passive chips 25A and 25B, and bonding wires 29A to 29D. Passive chip 25B, semiconductor chip 20, and passive chip 25B are arrayed along the Y direction.

Semiconductor chip 20 includes a substrate 21 and electrodes 22 and 23 provided on substrate 21. Substrate 21 is provided with, for example, a transistor. Electrodes 22 and 23 are, for example, an input electrode and an output electrode of the transistor. When the transistor is a field effect transistor (FET), the source, the gate, and the drain of the transistor are electrically connected to base portion 11, electrode 22, and electrode 23, respectively, for example.

Substrate 21 is a semiconductor substrate, and electrodes 22 and 23 are metal layers such as layers of gold, copper or the like. When the transistor is a GaN HEMT (High Electron Mobility Transistor), substrate 21 is, for example, a silicon carbide (SiC) substrate, a sapphire substrate, or a gallium nitride (GaN) substrate.

Passive chips 25A and 25B each include a substrate 26 and an electrode 27 provided on substrate 26. Substrate 26 is a dielectric substrate made of alumina, barium titanate, or the like. Substrate 26, together with electrode 27 and base portion 11 sandwiching substrate 26, forms a capacitor.

Bonding wires 29A electrically connect a line 32 of line chip 30A and electrode 27 of passive chip 25A. Bonding wires 29B electrically connect electrode 27 of passive chip 25A and electrode 23. Bonding wires 29C electrically connect electrode 22 and electrode 27 of passive chip 25B. Bonding wires 29D electrically connect electrode 27 of passive chip 25B and line 32 of line chip 30B.

Bonding wires 29A to 29D form inductors. Bonding wires 29A, passive chip 25A, and bonding wires 29B function as a matching circuit configured to match an impedance seen from electrode 23 toward bonding wires 29B and an impedance seen from bonding wires 29A toward line chip 30A. Bonding wires 29C, passive chip 25B, and bonding wires 29D function as a matching circuit configured to match an impedance seen from line chip 30B toward bonding wires 29D and an impedance seen from bonding wires 29C toward electrode 22.

Each of line chips 30A and 30B includes a substrate 31 and line 32 provided on substrate 31. In line chip 30A, line 32 forms a signal combiner configured to combine four input lines into one output line. The first ends of bonding wires 29A of amplifiers 28A to 28D are connected to four respective input lines of line 32. In line chip 30B, line 32 forms a signal distributor configured to branch one input line into four output lines. The first ends of bonding wires 29D of amplifiers 28A to 28D are connected to four respective output lines of line 32. Bonding wires 29E electrically connect one output line of line chip 30A and lead 15A. Bonding wires 29F electrically connect one input line of line chip 30B and lead 15B.

A high frequency signal input from lead 15B is branched into four by line chip 30B. The four branched high frequency signals are input to respective amplifiers 28A to 28D. The high frequency signals amplified by amplifiers 28A to 28D are combined by line chip 30A. The combined high frequency signal is output from lead 15A.

The number of semiconductor chips 20 provided in frame body 12 may be one or more. At least one of passive chip 25A, passive chip 25B, line chip 30A, and line chip 30B may not be provided. Although the example in which the transistor handling the high frequency signal is provided in semiconductor chip 20 has been described, a semiconductor element used for a power conversion circuit may be provided in semiconductor chip 20.

### (Module of First Embodiment)

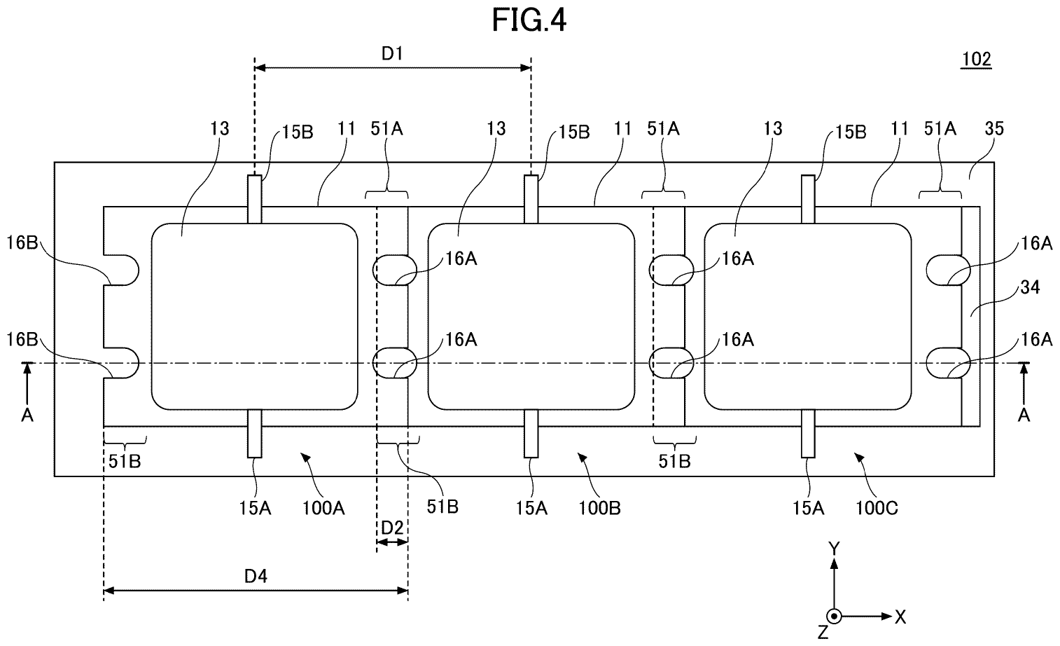

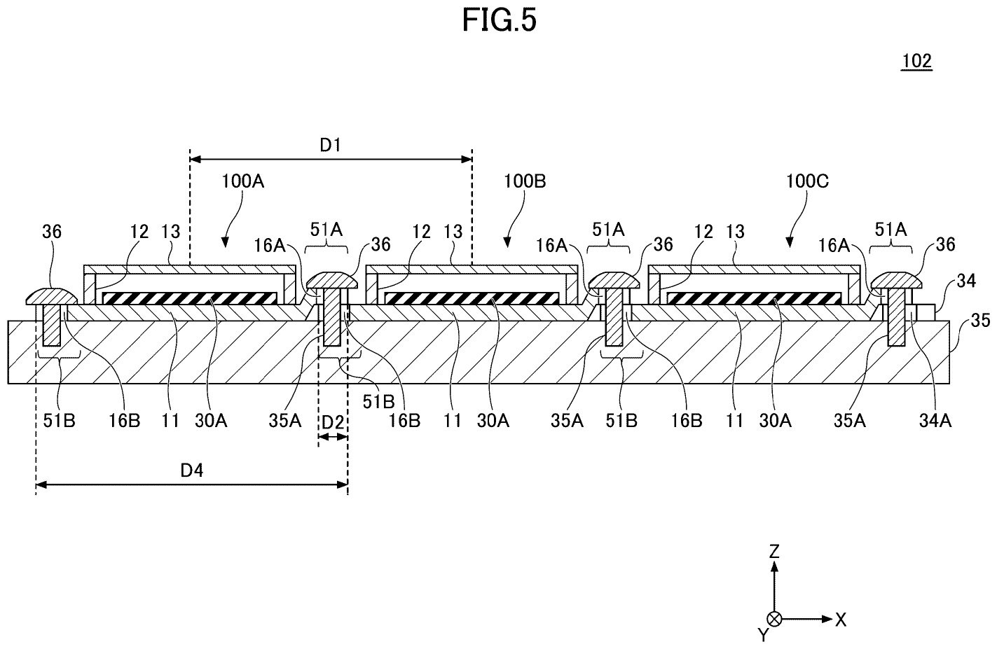

FIG. 4 is a plan view of a module according to the first embodiment. FIG. 5 is a cross-sectional view taken along line A-A of FIG. 4. In FIG. 4, screws are not shown.

As shown in FIGS. 4 and 5, a module 102 according to the first embodiment includes substrate 35 and a plurality of semiconductor devices 100A to 100C. The plurality of semiconductor devices 100A to 100C are arranged in the X direction on substrate 35.

The plurality of semiconductor devices 100A to 100C are mounted on substrate 35 such that mounting surfaces 54 of the plurality of semiconductor devices 100A to 100C are positioned on the upper surface of substrate 35.

End portion 51B of semiconductor device 100B is sandwiched between end portion 51A of semiconductor device 100A and substrate 35 in the Z-direction. When viewed from the Z direction, notch 16A of semiconductor device 100A and notch 16B of semiconductor device 100B substantially overlap each other. A screw 36 passes through notch 16A of semiconductor device 100A and notch 16B of semiconductor device 100B.

End portion 51B of semiconductor device 100C is sandwiched between end portion 51A of semiconductor device 100B and substrate 35 in the Z direction. When viewed from the Z direction, notch 16A of semiconductor device 100B and notch 16B of semiconductor device 100C substantially overlap each other. Screw 36 passes through notch 16A of semiconductor device 100B and notch 16B of semiconductor device 100C. A spacer 34 is positioned between end portion 51A of semiconductor device 100C and substrate 35. When viewed from the Z direction, notch 16A of semiconductor device 100C substantially overlaps with a notch 34A provided in spacer 34. Screw 36 passes through notch 16A of semiconductor device 100C and notch 34A of spacer 34. Screw 36 passes through notch 16B of semiconductor device 100A.

There is no overlapping semiconductor device at end portion 51A of semiconductor device 100C. Thus, the lower surface of end portion 51A of semiconductor device 100C may alternatively be at the same position as mounting surface 54 in the Z direction.

Screw 36 is fitted into a screw hole 35A of substrate 35. By tightening screw 36, the head of screw 36 is pressed toward substrate 35. Thus, semiconductor devices 100A to 100C are fixed to substrate 35. Substrate 35 is a heat sink such as an aluminum plate or a copper plate. Semiconductor devices 100A to 100C are fixed to substrate 35, and thus heat generated in each of semiconductor devices 100A to 100C is conducted to substrate 35. Thus, the rise in temperature of semiconductor devices 100A to 100C can be reduced. When amplifiers 28A to 28D are power amplifiers or when semiconductor devices 100A to 100C are used in a power conversion circuit, semiconductor devices 100A to 100C generate a substantial amount of heat. Thus, it is required to screw semiconductor devices 100A to 100C to substrate 35. Further, by supplying a reference potential such as a ground potential to substrate 35, the reference potential can be stably supplied to semiconductor devices 100A to 100C. When semiconductor devices 100A to 100C handle high frequency signals, high-frequency characteristics would be degraded if the reference potentials of semiconductor devices 100A to 100C were not stable. For these reasons, it is required to screw semiconductor devices 100A to 100C to substrate 35.

### First Comparative Example

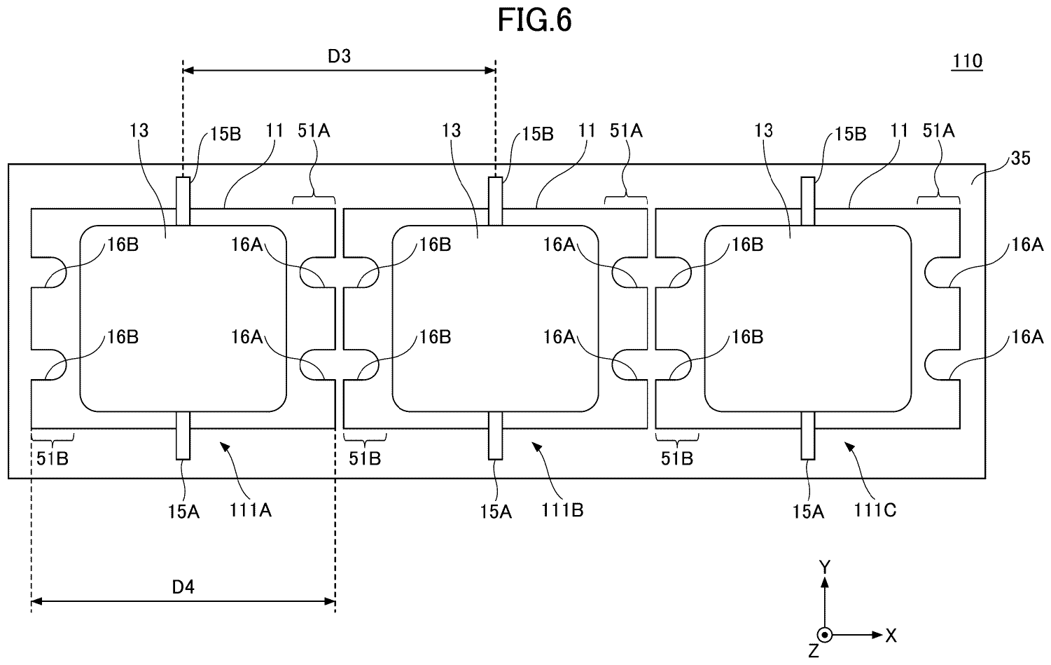

FIG. 6 is a plan view of a module according to a first comparative example. In FIG. 6, screws are not shown. As shown in FIG. 6, in a module 110 of the first comparative example, a plurality of semiconductor devices 111A to 111C are arranged in the X direction. In the first comparative example, flange 50A and flange 50B can be screwed to substrate 35, and thus the heat dissipation from semiconductor devices 111A to 111C to substrate 35 can be improved. Thus, the rise in temperature of semiconductor devices 111A to 111C can be reduced. In addition, the reference potential can be stably supplied to semiconductor devices 111A to 111C. Thus, the deterioration of the high-frequency characteristics of semiconductor devices 111A to 111C can be suppressed. In each of semiconductor devices 111A to 111C, both end portion 51A of flange 50A and end portion 51B of flange 50B are flat. Thus, end portions 51A and 51B cannot overlap each other when viewed from the Z direction.

Thus, an interval D3 between semiconductor devices 111A and 111B is equal to or larger than a width D4 in the X direction of each of semiconductor devices 111A to 111C. Thus, the area occupied by mounted semiconductor devices 111A to 111C is increased.

Using a bonding member such as solder instead of providing flanges 50A and 50B is a conceivable alternative for fixing semiconductor devices to substrate 35. However, compared to the first comparative example in which the semiconductor devices are directly fixed to substrate 35, since the bonding member is interposed between semiconductor devices and substrate 35, the heat dissipation and the electrical contact are deteriorated. In particular, voids and the like are likely to be generated in the bonding member, resulting in further deterioration in the heat dissipation and the electrical contact.

### Second Comparative Example

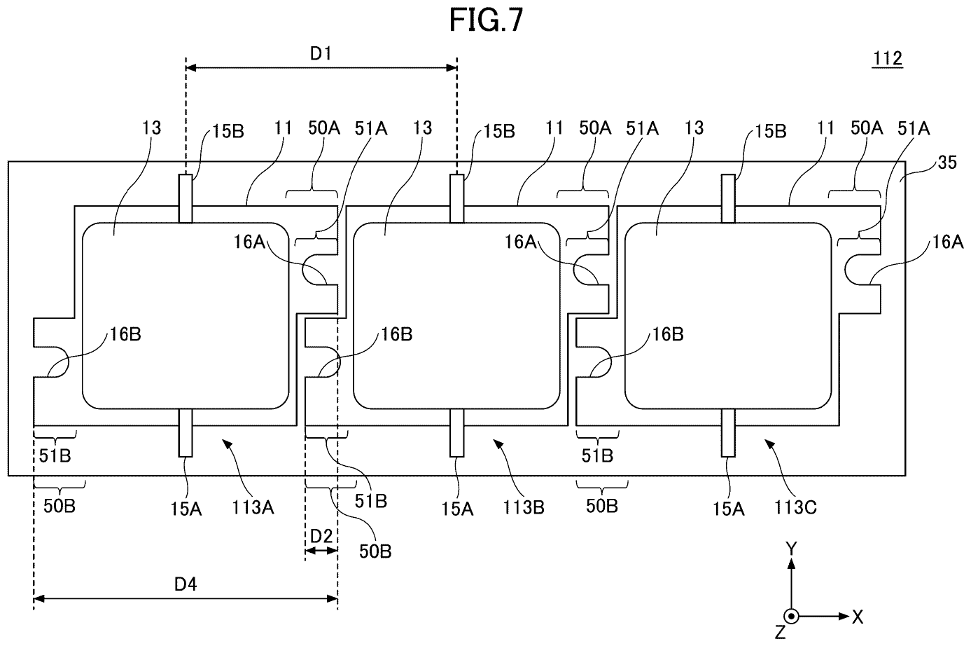

FIG. 7 is a plan view of a module according to a second comparative example. In FIG. 7, screws are not shown. As shown in FIG. 7, in a module 112 of the second comparative example, a plurality of semiconductor devices 113A to 113C are arranged in the X direction. In each of semiconductor devices 113A to 113C, both end portion 51A of flange 50A and end portion 51B of flange 50B are flat. End portion 51A of flange 50A is provided in the part of the flange 50A in the positive Y direction, and is absent in the part of the flange 50A in the negative Y direction. End portion 51B of flange 50B is provided in the part of flange 50B in the negative Y direction, and is absent in the part of flange 50B in the positive Y direction.

When viewed from the Y direction, end portion 51A of semiconductor device 113A and end portion 51B of semiconductor device 113B overlap each other. The width in the X direction of the overlap between end portion 51A of semiconductor device 113A and end portion 51B of semiconductor device 113B is defined as D2. At this time, an interval D1 between semiconductor devices 113A and 113B in the X direction can be made smaller than width D4 of each of semiconductor devices 113A to 113C in the X direction by a width D2.

However, semiconductor devices 113A to 113C are fixed to substrate 35 by screwing at notch 16A of end portion 51A and notch 16B of end portion 51B. Since semiconductor devices 113A to 113C are fixed at the opposing corners of the rectangular planar shapes of semiconductor devices 113A to 113C, the fixation of semiconductor devices 113A to 113C is not stable. Thus, the heat dissipation from semiconductor devices 113A to 113 to substrate 35 is deteriorated. Thus, the temperatures of semiconductor devices 113A to 113C may rise. Further, the supply of the reference potential to semiconductor devices 113A to 113C becomes unstable. Thus the high-frequency characteristics of semiconductor devices 113A to 113C may be deteriorated.

### (Description of First Embodiment)

According to semiconductor device 100 of the first embodiment, flange 50A (first flange) and flange 50B (second flange) are disposed such that accommodating portion 52 for housing semiconductor chip 20 is interposed therebetween in the X direction. As shown in FIG. 2, the lower surface of the end portion (first end portion) in the positive X direction of flange 50A is positioned above mounting surface 54 of accommodating portion 52. A distance DA (first distance) in the Z direction between the lower surface of end portion 51A and mounting surface 54 is equal to or greater than a distance DB (second distance) in the Z direction between the upper surface of end portion 51B (second end portion) in the negative X direction (opposite the first direction) of flange 50B and mounting surface 54. End portion 51A has notch 16A (first notch), and end portion 51B has notch 16B (second notch).

Thus, as shown in FIGS. 4 and 5, in module 102 of the first embodiment, end portion 51B of semiconductor device 100B (second semiconductor device) can be provided between end portion 51A of semiconductor device 100A (first semiconductor device) and substrate 35. Further, semiconductor devices 100A and 100B can be fixed on substrate 35 by the common screw 36 (fixture) passing through notch 16A of semiconductor device 100A and notch 16B of semiconductor device 100B. Thus, interval D1 between semiconductor devices 100A and 100B in the X direction can be made smaller than width D4 of each of semiconductor devices 100A and 100B in the X direction by width D2 of each of end portions 51A and 51B overlapping in the X direction. Thus, the mounting interval of semiconductor devices 100A to 100C can be shortened compared to FIG. 6 of the first comparative example. Screw 36 has been described as an example of the fixture, but the fixture is not limited to screw 36.

Further, end portion 51A of semiconductor device 100A and end portion 51B of semiconductor device 100B can be fixed to substrate 35 by the common screw 36. Thus, semiconductor devices 100A to 100C can be stably fixed to substrate 35 as compared with FIG. 7 of the second comparative example. Thus, the heat dissipation from semiconductor devices 100A to 100C to substrate 35 can be improved. Thus, the rise in temperature of semiconductor devices 100A to 100C can be reduced. In addition, the reference potential can be stably supplied to semiconductor devices 100A to 100C. Thus, the high-frequency characteristics of semiconductor devices 100A to 100C can be improved.

When the difference between distance DA and distance DB is large, space is formed between end portion 51A of semiconductor device 100A and end portion 51B of semiconductor device 100B when end portion 51A and end portion 51B are screwed together. The difference between distances DA and DB may be equal to or less than a half, or equal to or less than a quarter, of distance DB. This arrangement enables more stable fixation of semiconductor devices 100A to 100C to substrate 35. Distance DB is, for example, 0.5 mm to 3 mm.

As shown in FIG. 1, according to semiconductor device 100, the position of notch 16A in the Y direction coincides with the position of notch 16B in the Y direction. Thus, as shown in FIG. 4, semiconductor devices 100A to 100C can be arranged in the X direction in module 102. The arrangement direction of semiconductor devices 100A to 100C coincides with the arrangement direction of flanges 50A and 50B in each of semiconductor devices 100A to 100C.

Note that “the position of notch 16A in the Y direction coincides with the position of notch 16B in the Y direction” may include cases where they do not strictly coincide. For example, the difference in position between notch 16A and 16B may be equal to or less than a half, or equal to or less than a quarter, of the width of each of notch 16A and 16B in the Y direction. The positions of notches 16A and 16B in the Y direction refer to the center positions of notches 16A and 16B in the Y direction. Further, The term “coincide” with respect to two directions does not necessarily imply exact alignment. For example, the angle between the two directions may be 10 degrees or less, or 5 degrees or less.

As shown in FIG. 1, a plurality of notch 16A are arranged in the Y direction, and a plurality of notch 16B are arranged in the Y direction. Thus, as shown in FIGS. 4 and 5, when semiconductor devices 100A to 100C are fixed to substrate 35 using screws 36, semiconductor devices 100A to 100C can be stably fixed to substrate 35. Although semiconductor device 100 of the first embodiment includes two notches 16A and two notches 16B, the number of notches 16A and the number of notches 16B may alternatively be three or more.

As shown in FIG. 1, at least two of a plurality of notches 16A are arranged with a center line 55 in the Y direction of package 10 being interposed therebetween. At least two of a plurality of notches 16B are arranged with center line 55 in the Y direction of package 10 being interposed therebetween. This arrangement enables more stable fixation of semiconductor devices 100A to 100C to substrate 35. The distance in the Y direction between the center positions in the Y direction of the outermost notches 16A among a plurality of notches 16A can be set to be equal to or greater than one-third of the width of each of flanges 50A and 50B in the Y direction. This arrangement enables more stable fixation of semiconductor devices 100A to 100C to substrate 35. The width of each of flanges 50A and 50B in the Y direction is, for example, 1 mm to 5 mm, and the distance in the Y direction between the Y-direction center positions of notches 16A is, for example, 0.3 mm to 2 mm.

As shown in FIG. 1, the plurality of notches 16A are provided in line symmetry with respect to center line 55 in the Y direction of package 10, and the plurality of notches 16B are provided in line symmetry with respect to center line 55 in the Y direction of package 10.

As shown in FIGS. 2 and 3, the upper surface of end portion 51A is positioned above (in the positive Z direction of) the upper surface of end portion 51B. Thus, end portion 51A can be formed by bending flange 50A. Thus, end portion 51A can be easily formed.

The upper surface of end portion 51A and the upper surface of end portion 51B are parallel to mounting surface 54. Thus, upon fixing semiconductor devices 100A to 100C to substrate 35 using screws 36, a more stable fixation of semiconductor devices 100A to 100C to substrate 35 can be achieved. Note that the term “parallel,” when referring to two surfaces, does not necessarily require exact parallel alignment. For example, the angle between the two surfaces may be 10 degrees or less, or 5 degrees or less.

From the viewpoint of miniaturizing module 102, interval D1 between semiconductor devices 100A and 100B in the X direction may be set to no more than 0.95 times, or no more than 0.9 times, width D4 of each of semiconductor devices 100A and 100B in the X direction. From the viewpoint of increasing accommodating portion 52, interval D1 may be set to be no less than 0.5 times width D4. Interval D1 is, for example, 5 mm to 50 mm, and width D4 is, for example, 5 mm to 50 mm.

### (Modification 1 of First Embodiment)

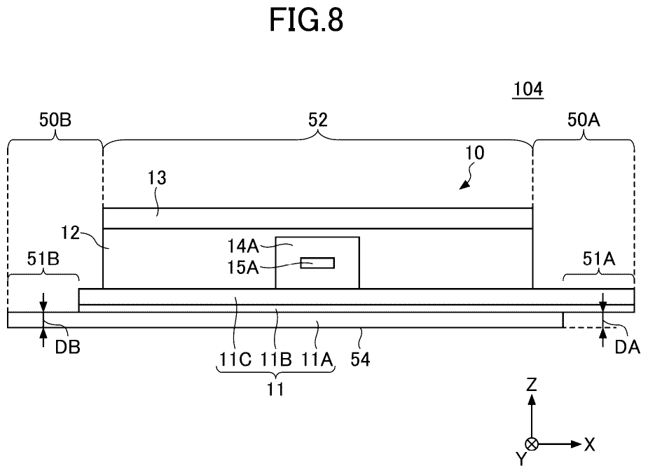

FIG. 8 is a side view of a semiconductor device according to a modification 1 of the first embodiment. As shown in FIG. 8, in a semiconductor device 104 according to the modification 1 of the first embodiment, base portion 11 includes a first layer 11A, a second layer 11B, and a third layer 11C. First layer 11A and third layer 11C sandwich second layer 11B in the Z direction. Frame body 12 is positioned on third layer 11C. End portion 51A does not include first layer 11A, but includes second layer 11B and third layer 11C. End portion 51B does not include second layer 11B or third layer 11C, but includes first layer 11A. The part of base portion 11 other than end portions 51A and 51B includes first layer 11A, second layer 11B, and third layer 11C. First layer 11A, second layer 11B, and third layer 11C are metal layers. First layer 11A and third layer 11C are, for example, copper layers, and second layer 11B is, for example, a molybdenum layer.

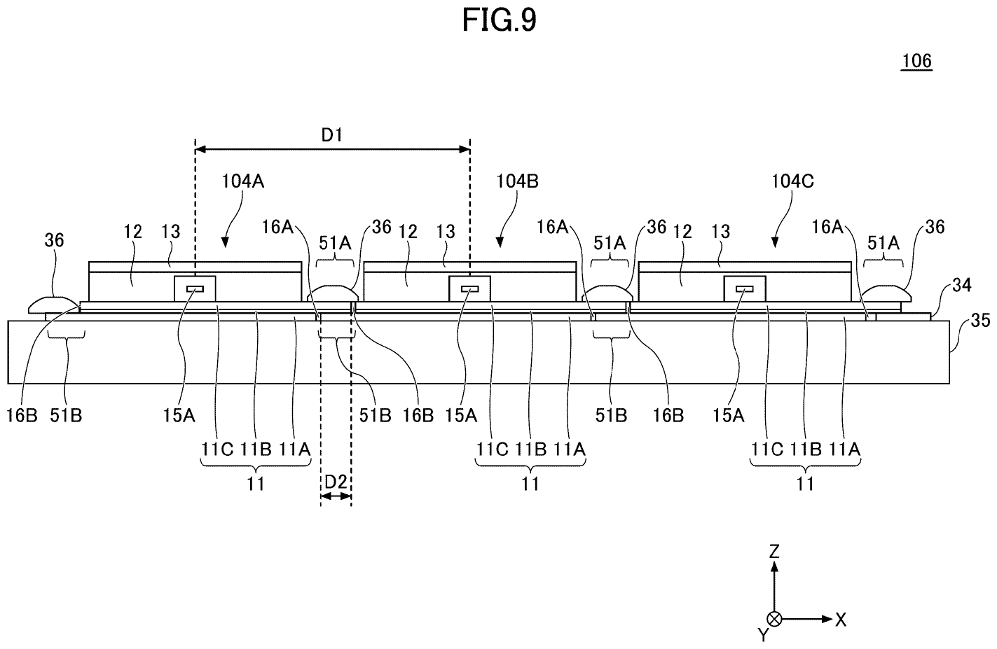

FIG. 9 is a side view of a module according to the modification 1 of the first embodiment. As shown in FIG. 9, in a module 106 according to the modification 1 of the first embodiment, first layer 11A of end portion 51B of a semiconductor device 104B is disposed between second layer 11B of end portion 51A of a semiconductor device 104A and substrate 35. First layer 11A of end portion 51B of a semiconductor device 104C is disposed between second layer 11B of end portion 51A of semiconductor device 104B and substrate 35. Other configurations are the same as those of the first embodiment, and the description thereof will be omitted.

According to the modification 1 of the first embodiment, flange 50A has second layer 11B and third layer 11C, and flange 50B has first layer 11A. First layer 11A, second layer 11B, and third layer 11C are stacked in the Z direction. End portion 51A includes second layer 11B and third layer 11C, but does not include first layer 11A. End portion 51B includes first layer 11A, but does not include second layer 11B or third layer 11C. Thus, distance DA between mounting surface 54 and the lower surface of end portion 51A in the Z direction and distance DB between mounting surface 54 and the upper surface of end portion 51B in the Z direction both correspond to the thickness of first layer 11A and can be substantially equal to each other. This arrangement enables more stable fixation of semiconductor devices 102A to 102C to substrate 35. Although the example in which three layers are stacked in base portion 11 has been described, two layers or four or more layers may alternatively be stacked in base portion 11.

### (Modification 2 of First Embodiment)

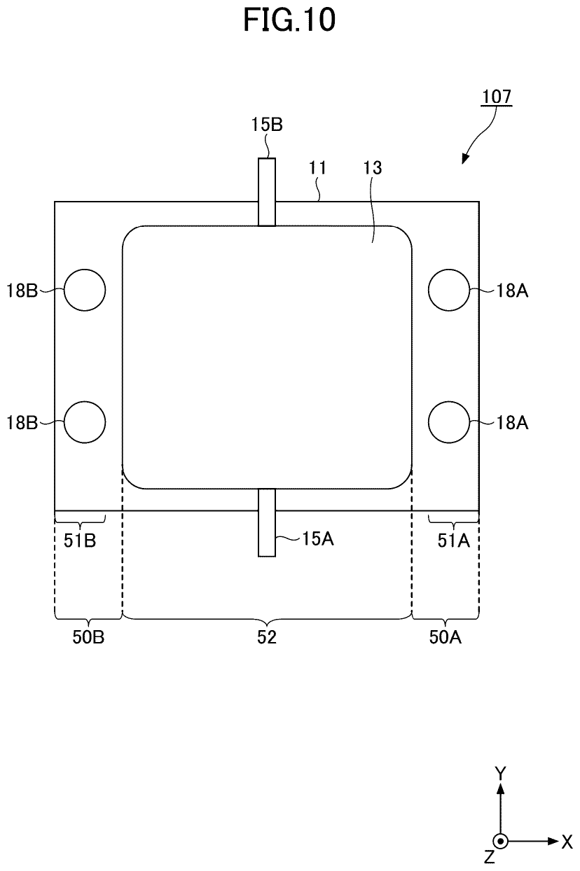

FIG. 10 is a plan view of a semiconductor device according to a modification 2 of the first embodiment. As shown in FIG. 10, in a semiconductor device 107 according to the modification 2 of the first embodiment, openings 18A (first opening) and 18B (second opening) penetrating base portion 11 in the Z direction are provided in end portions 51A and 51B, respectively. Other configurations are the same as those of the first embodiment, and the description thereof will be omitted.

As in the modification 2 of the first embodiment, openings 18A and 18B may be provided instead of notches 16A and 16B. Notches 16A and 16B each have a planar shape in the XY plane, with one open side and three closed sides surrounded by base portion 11. Openings 18A and 18B each have a planar shape with an enclosed boundary and is surrounded by base portion 11 in the XY plane.

### Second Embodiment

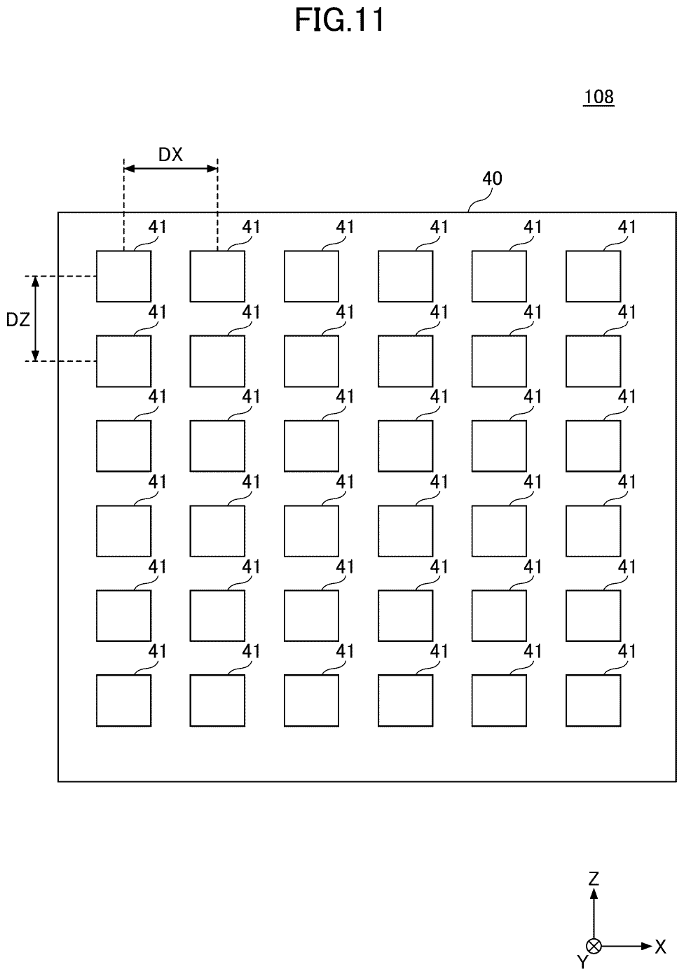

A second embodiment is an example in which the modules of the first embodiment and its modifications are used in a phased array antenna device. FIG. 11 is a front view of antennas in a phased array antenna device according to the second embodiment. FIG. 11 is a view from the Y direction.

As shown in FIG. 11, in a phased array antenna device 108, antennas 41 are arranged in a matrix in the X direction and the Z direction on a substrate 40. An interval between antennas 41 in the X direction is DX, and an interval between antennas 41 in the Z direction is DZ. Interval DX is substantially constant, and interval DZ is substantially constant. Intervals DX and DZ may be substantially equal to each other. Antennas 41 are, for example, patch antennas.

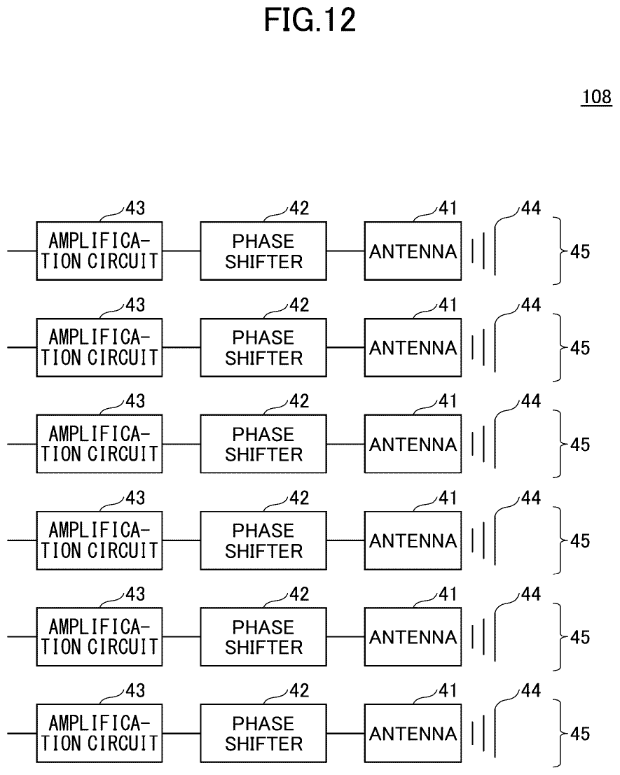

FIG. 12 is a block diagram of the phased array antenna device according to the second embodiment. As shown in FIG. 12, phased array antenna device 108 includes a plurality of blocks 45. Each of the plurality of blocks 45 includes an amplification circuit 43, a phase shifter 42, and antenna 41.

When phased array antenna device 108 transmits a radio wave, a high frequency signal is input to amplification circuit 43. Amplification circuit 43 amplifies the high frequency signal. Phase shifter 42 causes the phase of the amplified high frequency signal to be shifted. Antenna 41 emits the phase-shifted high frequency signal into space as a radio wave 44. For example, in blocks 45 arranged in the Z direction, phases shifted by phase shifters 42 increase along the Z direction. By setting the amount of increase in the phase for each block 45, directivity can be provided in any direction as desired, which is inclined in the Z direction relative to the Y direction. The same applies to blocks 45 arranged in the X direction.

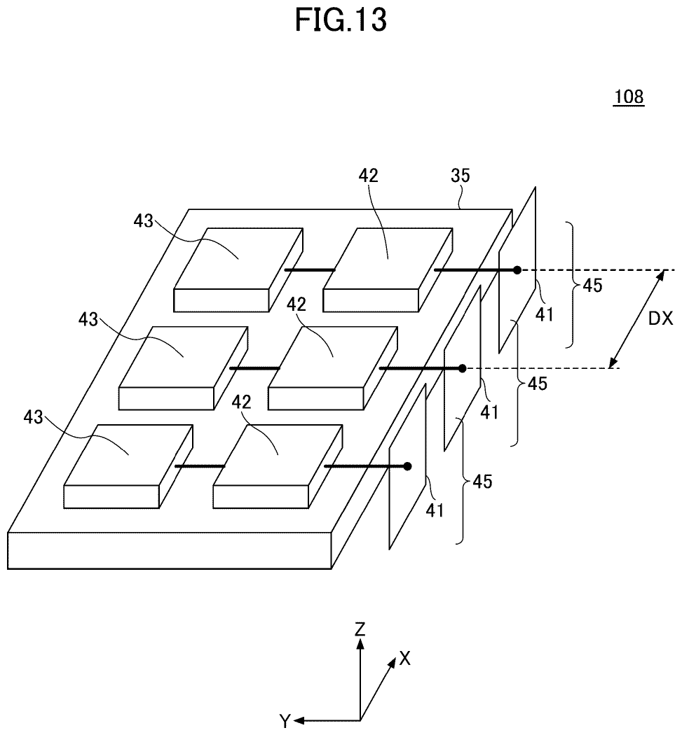

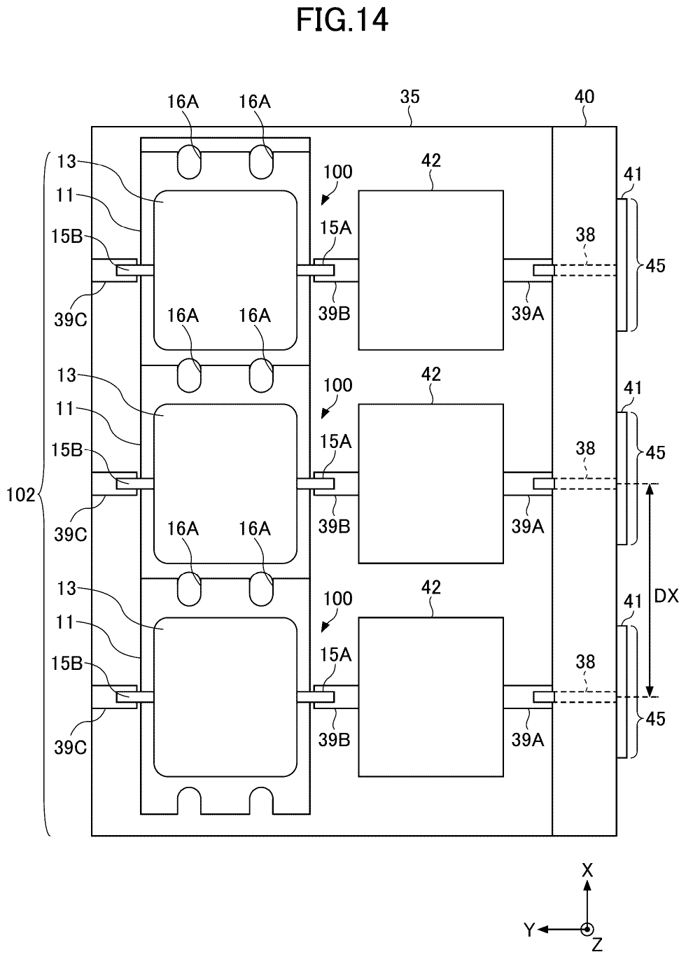

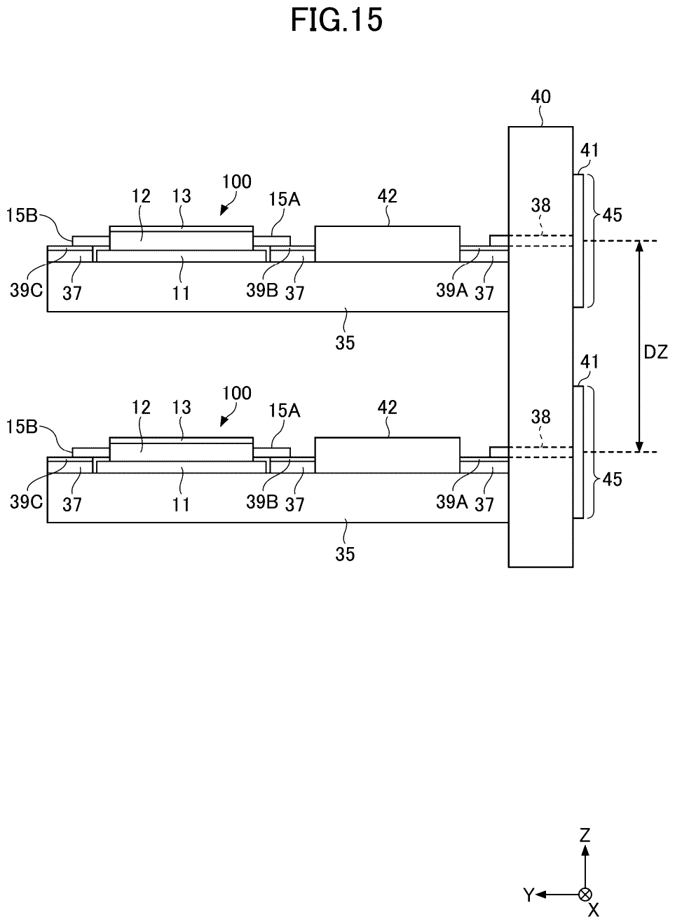

FIG. 13 is an oblique view of a portion of the phased array antenna device according to the second embodiment. In FIG. 13, three blocks 45 arranged in the X direction are shown, and substrate 40 is not shown. FIG. 14 is a plan view of the portion of phased array antenna device 108 according to the second embodiment. FIG. 14 is a plan view showing three blocks 45 arranged in the X direction, as viewed from the Z direction. FIG. 15 is a side view of a portion of the phased array antenna device according to the second embodiment. FIG. 15 is a side view showing two blocks 45 arranged in the Z direction, as viewed from the X direction.

As shown in FIGS. 13 to 15, a plurality of substrates 35 are provided on substrate 40 provided with antennas 41 so as to sandwich substrate 40 between themselves and antennas 41 in the Y direction. Substrates 35 are arranged in the Z direction. Module 102 of the first embodiment, phase shifters 42, and line patterns 39A to 39C are provided on one substrate 35. Line patterns 39A to 39C are provided with an insulating layer 37 interposed between line patterns 39A to 39C and substrate 35.

A line 38 is provided through substrate 40. Line 38 electrically connects antenna 41 and line pattern 39A. Line pattern 39A electrically connects line 38 and phase shifter 42. Line pattern 39B electrically connects phase shifter 42 and lead 15A. Line pattern 39C is connected to lead 15B. Semiconductor chip 20 in each of semiconductor devices 100A to 100C includes amplification circuit 43.

A high frequency signal input to line pattern 39C is input to semiconductor device 100 through lead 15B. The high frequency signal amplified by amplification circuit 43 of semiconductor device 100 is input to phase shifter 42 via lead 15A and line pattern 39B. The high frequency signal whose phase has been shifted by phase shifter 42 passes through line pattern 39A and line 38 to be emitted from antenna 41 to space.

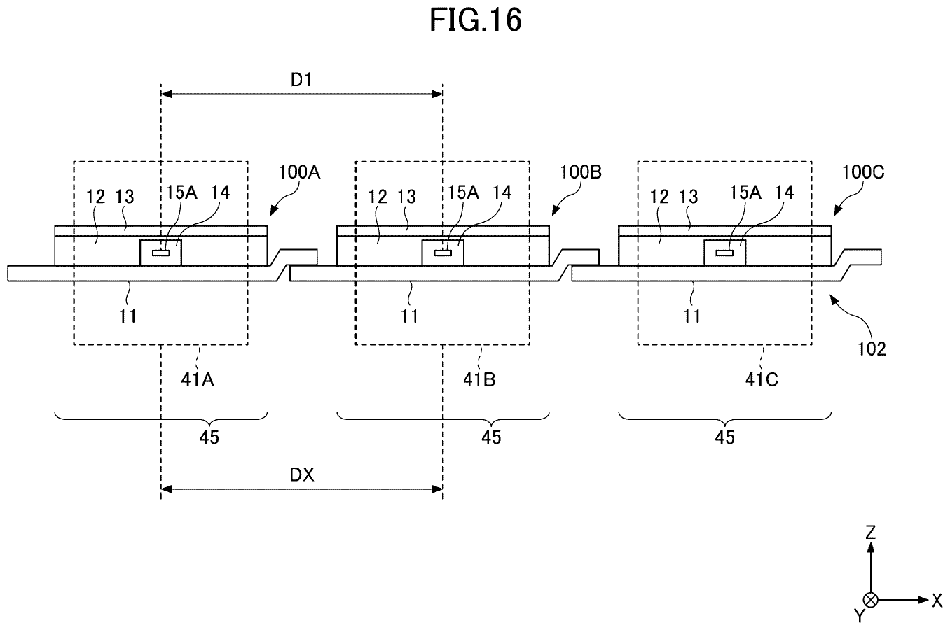

FIG. 16 is a front view of a module and antennas of the phased array antenna device according to the second embodiment. FIG. 16 is a plan view in which antennas 41A to 41C overlap module 102 when viewed from the Y direction. Intervals D1 between semiconductor devices 100A to 100C and intervals DX between antennas 41A to 41C are equal to each other. This is because, when interval D1 and interval DX are different, the electrical distance between leads 15A of semiconductor devices 100A to 100C and antennas 41A to 41C varies depending on block 45, which results in the difficulty to control the phases of high frequency signals between blocks 45.

In phased array antenna device 108, in order to increase the directivity of radio waves, each of intervals DX and DZ between antennas 41A to 41C is ideally equal to λ/2. Here, λ is a wavelength in vacuum of radio wave radiated by each of antennas 41A to 41C. Even if antenna characteristics are somewhat sacrificed, DX and DZ are required to be 2×λ/3 or less. When frequency of the radio wave is 5 GHZ, λ/2 and 2×λ/3 are 30 mm and 40 mm, respectively. When the frequency of the radio wave is 10 GHZ, λ/2 and 2×λ/3 are 15 mm and 20 mm, respectively. Thus, as frequencies of signals increase, it is necessary to reduce interval DX of antenna 41, so that interval D1 between leads 15A of semiconductor devices 100 and the like is required to be reduced.

According to the second embodiment, when viewed from the Y direction, antenna 41A (first antenna) overlaps semiconductor device 100A (first semiconductor device), and antenna 41B (second antenna) overlaps semiconductor device 100B (second semiconductor device). Thus, since intervals D1 between semiconductor devices 100A to 100C can be reduced as in the first embodiment and its modifications, intervals DX between antennas 41A to 41C can be reduced. Thus, a phased array antenna device that handles higher frequencies can be provided.

Amplification circuit 43 (first amplification circuit) of semiconductor device 100A outputs the amplified high frequency signal to antenna 41A, and amplification circuit 43 (second amplification circuit) of semiconductor device 100B outputs the amplified high frequency signal to antenna 41B. As described above, when semiconductor devices 100A to 100C include power amplifiers, semiconductor devices 100A to 100C are likely to become high temperatures. In consideration of this, flanges 50A and 50B are screwed. Thus, the rise in temperature of semiconductor devices 100A to 100C can be reduced.

In the second embodiment, an example in which six antennas 41 are arranged in the X direction and six antennas 41 are arranged in the Z direction has been described. However, it is only required that at least two antennas 41 are arranged in the X direction. The frequencies of radio waves 44 of phased array antenna device 108 are, for example, 5 GHz or more, and 10 GHz or more.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. A semiconductor device comprising:
a semiconductor chip; and
a package including an accommodating portion that houses the semiconductor chip, and a first flange and a second flange arranged along a first direction with the accommodating portion being interposed between the first flange and the second flange, the first flange being positioned in the first direction relative to the accommodating portion, the second flange being positioned in an opposite direction to the first direction relative to the accommodating portion, wherein a lower surface of a first end portion, in the first direction, of the first flange is positioned above a mounting surface of the accommodating portion, and a first distance between the lower surface of the first end portion and the mounting surface in a second direction orthogonal to the mounting surface is equal to or greater than a second distance between an upper surface of a second end portion, in the opposite direction, of the second flange and the mounting surface in the second direction, and wherein the first end portion has at least one first opening or at least one first notch penetrating the first end portion in the second direction, and the second end portion has at least one second opening or at least one second notch penetrating the second end portion in the second direction.

2. The semiconductor device according to claim 1, wherein the at least one first opening or the at least one first notch comprises a plurality of first openings or a plurality of first notches that are arranged in a third direction orthogonal to the first direction and the second direction, and the at least one second opening or the at least one second notch comprises a plurality of second openings or a plurality of second notches that are arranged in the third direction.

3. The semiconductor device according to claim 2, wherein at least two of the plurality of first openings or at least two of the plurality of first notches are arranged with a center line of the package in the third direction being interposed therebetween, and wherein at least two of the plurality of second openings or at least two of the plurality of second notches are arranged with the center line of the package in the third direction being interposed therebetween.

4. The semiconductor device according to claim 1, wherein a position of the at least one first opening or the at least one first notch in a third direction orthogonal to the first direction and the second direction coincides with a position of the at least one second opening or the at least one second notch in the third direction.

5. The semiconductor device according to claim 1, wherein an upper surface of the first end portion is positioned above the upper surface of the second end portion with respect to the mounting surface.

6. The semiconductor device according to claim 1, wherein the first flange and the second flange each include a first layer and a second layer stacked in the second direction, wherein the first end portion includes the second layer and does not include the first layer, and wherein the second end portion includes the first layer and does not include the second layer.

7. The semiconductor device according to claim 1, wherein the at least one first opening or the at least one first notch, and the at least one second opening or at least one the second notch, are each configured to allow a fixture fixing the semiconductor device to a substrate to pass through.

8. A module comprising:
a substrate;
a first semiconductor device that has a same configuration as the semiconductor device of claim 1, the first semiconductor device being mounted on the substrate such that the mounting surface is positioned on an upper surface of the substrate; and
a second semiconductor device that has a same configuration as the semiconductor device of claim 1, the second semiconductor device being mounted on the substrate such that the mounting surface is positioned on the upper surface of the substrate, wherein the second end portion of the second semiconductor device is provided between the first end portion of the first semiconductor device and the substrate, and wherein the first semiconductor device and the second semiconductor device are fixed on the substrate by a common fixture passing through the at least one first opening or the at least one first notch, and through the at least one second opening or the at least one second notch.

9. The module according to claim 8, wherein an arrangement direction of the first semiconductor device and the second semiconductor device coincides with the first direction of the first semiconductor device and the first direction of the second semiconductor device.

10. A phased array antenna device comprising:
the module of claim 9; and
a first antenna and a second antenna arranged in the arrangement direction, wherein a third direction orthogonal to the first direction and the second direction of the first semiconductor device coincides with a direction orthogonal to the first direction and the second direction of the second semiconductor device, wherein the first antenna overlaps the first semiconductor device when viewed from the third direction, and wherein the second antenna overlaps the second semiconductor device when viewed from the third direction.

11. The phased array antenna device according to claim 10, wherein the first semiconductor device includes a first amplification circuit, wherein the second semiconductor device includes a second amplification circuit, wherein the first amplification circuit outputs an amplified high frequency signal to the first antenna, and wherein the second amplification circuit outputs an amplified high frequency signal to the second antenna.
